(19) United States
(12) Patent Application Publication
(10) Pub. No.: US 2024/0421778 A1
(43) Pub. Date: Dec. 19, 2024

(54) AMPLIFIER, AMPLIFICATION CIRCUIT, AND CURRENT DETECTION DEVICE

(71) Applicant: ROHM CO., LTD., Kyoto-shi (JP)

(72) Inventor: Akihiro OTA, Kyoto-shi (JP)

(21) Appl. No.: 18/816,089

(22) Filed: Aug. 27, 2024

Related U.S. Application Data
(63) Continuation of application No. PCT/JP2023/005201, filed on Feb. 15, 2023.

(30) Foreign Application Priority Data
Feb. 28, 2022 (JP) 2022-029030

(51) Int. Cl. H03F 3/16; G01R 19/00

(52) U.S. Cl. CPC H03F 3/16; G01R 19/0023

(57) ABSTRACT

An amplifier includes a first transistor, a second transistor arranged adjacent to the first transistor in plan view, a first conductor arranged around the first transistor and the second transistor in plan view, and a second conductor arranged, in plan view, in a direction farther away from the first transistor and the second transistor than the first conductor. The second conductor has a thickness that is greater than a thickness of the first conductor.

### CROSS-REFERENCE TO RELATED APPLICATIONS

This application is a continuation under 35 U.S.C. § 120 PCT/JP2023/005201 filed on Feb. 15, 2023, which is incorporated herein by reference, and which claimed priority to Japanese Patent Application No. 2022-029030 filed on Feb. 28, 2022. The present application likewise claims priority under 35 U.S.C. § 119 to Japanese Application No. 2022-029030, filed Feb. 28, 2022, the entire content of which is also incorporated herein by reference.

### TECHNICAL FIELD

The present disclosure relates to an amplifier.

### BACKGROUND ART

Conventionally, there has been known an amplifier (also referred to as an operational amplifier) having two input terminals, which amplifies the voltage difference between these two input terminals and outputs the amplified voltage difference. The amplifier is used in various amplification circuits (e.g., Patent Document 1).

### CITATION LIST

### Patent Literature

Patent Document 1: JP-A-2020-80486

### BRIEF DESCRIPTION OF DRAWINGS

FIG. 1 is a diagram illustrating a configuration example of an amplifier.

FIG. 2A is a plan view schematically illustrating a layout near transistors in an amplifier.

FIG. 2B is a diagram illustrating a modified example of a layout of PMOS transistors.

FIG. 2C is a diagram illustrating a modified example of a layout of PMOS transistors.

FIG. 3 is a diagram illustrating distribution of stress applied to an Si interface in the layout configuration of FIG. 2A, along with an example of a sectional configuration taken along line A-A.

FIG. 4 is a diagram illustrating a configuration example of an amplification circuit using amplifiers.

FIG. 5 is a diagram exemplarily illustrating variation in output voltage of an amplifier with temperature change.

FIG. 6 is a diagram schematically illustrating an example of a layout of conductors in an amplifier according to a first embodiment.

FIG. 7 is a diagram schematically illustrating an example of a layout of conductors in an amplifier according to a second embodiment.

FIG. 8 is a diagram illustrating a configuration example of a current detection device.

### DESCRIPTION OF EMBODIMENTS

Hereinafter, exemplary embodiments will be described with reference to the accompanying drawings.

### 1. Problems of Amplifiers

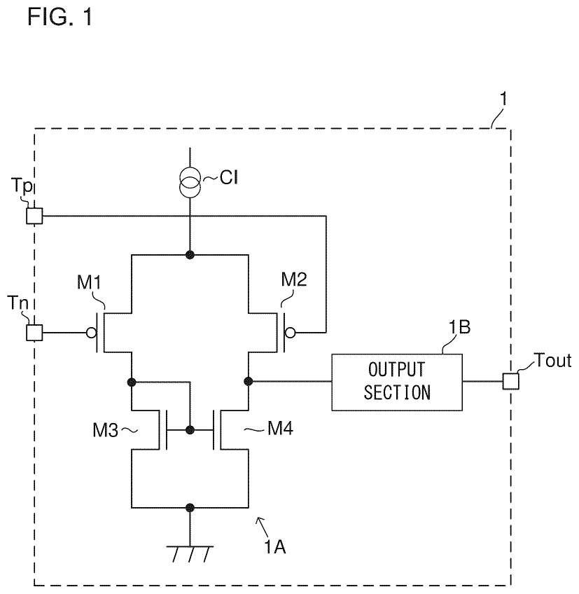

FIG. 1 is a diagram illustrating a configuration example of an amplifier. An amplifier 1 illustrated in FIG. 1 is a semiconductor integrated circuit that includes a differential input section 1A and an output section 1B. The amplifier 1 further includes a positive-side input terminal Tp, a negative-side input terminal Tn, and an output terminal Tout, for establishing external electrical connection.

The differential input section 1A includes PMOS transistors (P-channel MOSFET (metal-oxide-semiconductor field-effect transistor)) M1 and M2, NMOS transistors (N-channel MOSFET) M3 and M4, and a constant current source CI.

A gate of the PMOS transistor M1 is connected to a negative-side input terminal Tn. A gate of the PMOS transistor M2 is connected to the positive-side input terminal Tp. Sources of the PMOS transistors M1 and M2 are commonly connected to the constant current source CI. A drain of the PMOS transistor M1 is connected to a drain of the NMOS transistor M3. A gate and a drain of the NMOS transistor M3 are short circuited. The gate of the NMOS transistor M3 and a gate of the NMOS transistor M4 are connected to each other. Sources of the NMOS transistors M3 and M4 are commonly connected to a ground voltage application end. A drain of the NMOS transistor M4 is connected to a drain of the PMOS transistor M2.

A node where the PMOS transistor M2 and the NMOS transistor M4 are connected is connected to an input end of the output section 1B. An output end of the output section 1B is connected to the output terminal Tout. The output section 1B includes a gain stage and an output stage, of which neither is illustrated.

With the configuration described above, the amplifier 1 amplifies a voltage difference between the positive-side input terminal Tp and the negative-side input terminal Tn, and outputs an amplified voltage difference from the output terminal Tout.

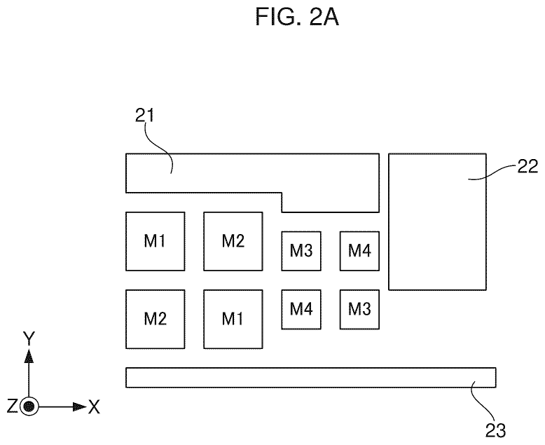

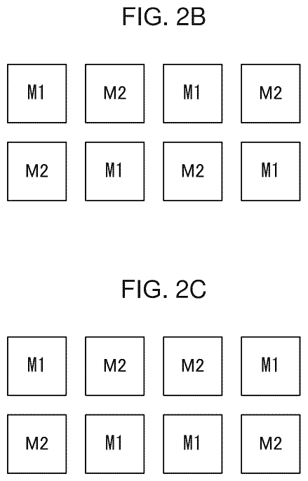

FIG. 2A is a plan view schematically illustrating a layout near the transistors M1 to M4 in the amplifier 1. FIG. 2A is a plan view as seen from above. In FIG. 2A, an up-down direction is defined as a Z direction, and two orthogonal directions on a plane orthogonal to the z direction are respectively defined as an X direction and a Y direction. The above direction definitions also apply to figures other than FIG. 2A.

As illustrated in FIG. 2A, two pairs of the PMOS transistors M1 and M2 matching of which is considered important are provided. In each of the two pairs, the PMOS transistors M1 and M2 are arranged adjacent to each other in the X direction. The two pairs of the PMOS transistors M1 and M2 are arranged adjacent to each other in the Y direction. The PMOS transistors M1 and M2 are arranged on diagonal lines that cross each other.

Further, as illustrated in FIG. 2A, two pairs of the NMOS transistors M3 and M4 matching of which is considered important are provided. In each of the two pairs, the NMOS transistors M3 and M4 are arranged adjacent to each other in the X direction. The two pairs of the NMOS transistors M3 and M4 are arranged adjacent to each other in the Y direction. The NMOS transistors M3 and M4 are arranged on diagonal lines that cross each other. The two pairs of the PMOS transistors M1 and M2 are arranged adjacent to the two pairs of the NMOS transistors M3 and M4 in the X direction.

The layout of the transistors the matching of which is considered important is not limited to the above-described one. For example, as illustrated in FIG. 2B or FIG. 2C, four pairs of the PMOS transistors M1 and M2 may be provided. For improvement of the matching, in FIG. 2B and FIG. 2C, the arrangement is such that a geometric centroid of an element group of the PMOS transistors M1 coincides with a geometric centroid of an element group of the PMOS transistors M2 (this also applies to FIG. 2A).

In the amplifier 1, above an Si (silicon) interface where the transistors M1 to M4 are formed, a plurality of layers (e.g., three layers) of conductors are formed. The conductor in an uppermost layer is a TOP conductor formed as an AL (aluminum) conductor. In FIG. 2A, for convenience, among the conductors, only the TOP conductor is illustrated. Note that the TOP conductor may be formed as a Cu (copper) conductor.

In the example illustrated in FIG. 2A, as the TOP conductor, TOP conductors 21, 22, and 23 are provided. The TOP conductor 21 is formed to extend in the X direction and arranged farther on one side in the Y direction than one group of two groups of the transistors M1 to M4 that is positioned on the one side in the Y direction. The TOP conductor 22 is formed to extend in the Y direction and arranged on one side, in the X direction, of the TOP conductor 21 and the NMOS transistor M4 that is positioned on the one side in the Y direction. The TOP conductor 23 is formed to extend in the X direction and arranged farther on the other side in the Y direction than the transistors M1 to M4 that are positioned on the other side in the Y direction.

In this manner, the TOP conductors 21 to 23 are provided around the transistors M1 to M4 and are arranged not to overlap with the transistors M1 to M4 in plan view. Other conductors (unillustrated in FIG. 2A), which are formed in lower layers than the TOP conductors 21 to 23, are also arranged, as much as possible, so as not to overlap with the transistors M1 to M4 in plan view.

With this layout of the conductors, it is possible to even out the influence that hydrogen annealing treatment has on the Si interface when performed during the process of forming the conductors, and thus to suppress mismatching between the PMOS transistors M1 and M2 the matching of which is considered important, and between the NMOS transistors M3 and M4 the matching of which is considered important. If the conductors overlap with the transistors M1 to M4, the hydrogen annealing treatment with respect to the transistors M1 to M4 will be performed unevenly.

However, there is a case where a thickness of the TOP conductors is increased (to, for example, 10 times the thickness of the conductors in the lower layers) to handle a large current. In such a case, heat stress of the TOP conductors significantly influences stress applied to the Si interface.

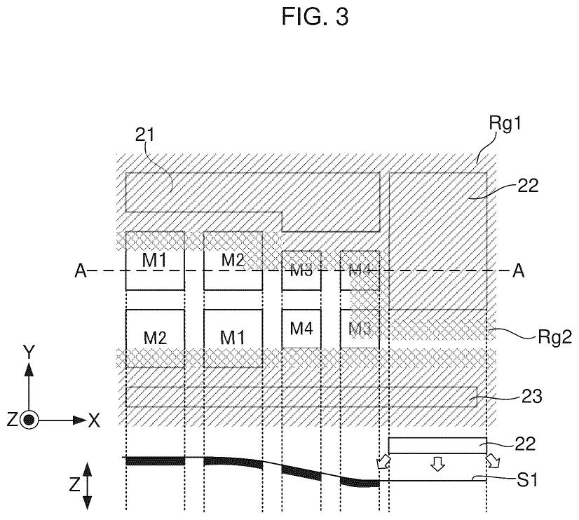

For example, in FIG. 3, the same layout configuration in plan view as illustrated in FIG. 2A is illustrated in an upper part of the figure. In FIG. 3, the distribution of the stress applied to the Si interface due to the heat stress of the TOP conductors 21 to 23 is illustrated to be superimposed on the layout configuration. Regions Rg1 and Rg2 are illustrated with different hatching patterns, and the region Rg2 is a region that receives smaller stress than the region Rg1. Regions where no hatching is applied are regions that receive even smaller stress than the region Rg2.

In a lower part of FIG. 3, a sectional configuration is illustrated that is taken along line A-A extending in the X direction in the upper part of the figure. Here, how the Si interface S1 is deformed is illustrated.

Due to the distribution of the stress applied to the Si interface due to the heat stress of the TOP conductors 21 to 23 as illustrated in FIG. 3, in the sectional view taken along line A-A, the Si interface S1 is displaced by an increasingly larger displacement amount from the transistor M1 toward the transistor M4. Thus, if the thickness of the TOP conductors is increased, the displacement amount of the Si interface increases due to the influence of the heat stress of the TOP conductors, and the difference in displacement amount between the transistors M1 and M2 and the difference in displacement amount between the transistors M3 and M4 are respectively increased due to the layout of the TOP conductors, as a result of which mismatching is caused. The mismatching causes an offset of the amplifier 1.

Due to the above-described increased difference in displacement amount of the Si interface, once the temperature changes, even if it is restored, the displacement does not fully recover, making it likely that hysteresis occurs in the offset. Offset hysteresis refers to a phenomenon in which, even when the temperature is restored to its original state, the offset does not fully recover but takes on multiple states.

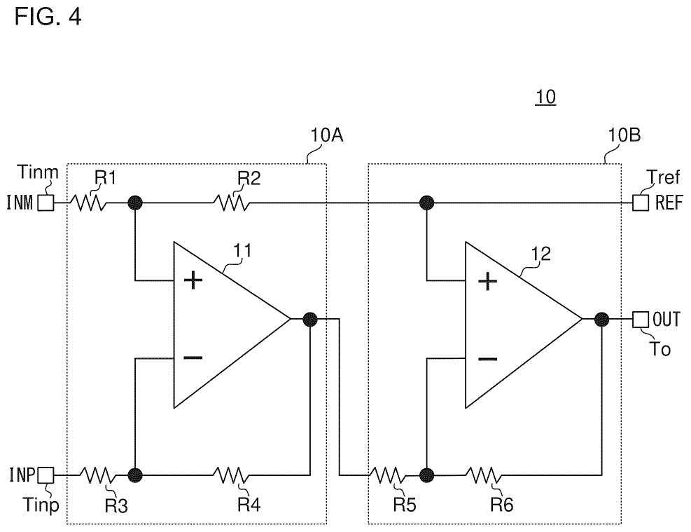

Here, FIG. 4 is a diagram illustrating a configuration example of an amplification circuit using the amplifier 1. An amplification circuit 10 illustrated in FIG. 4 includes an amplification section 10A of a first stage, and an amplification section 10B of a second stage. Further, the amplification circuit 10 includes a positive-side input terminal Tinp, a negative-side input terminal Tinm, a reference voltage terminal Tref, and an output terminal To. Used as each of amplifiers 11 and 12 in FIG. 4 is the amplifier 1 described previously.

The amplification section 10A includes the amplifier 11, and resistors R1 to R4. In terms of resistance, R1=R3 and R2=R4 hold.

One end of the resistor R1 is connected to the negative-side input terminal Tinm. A node at which the other end of the resistor R1 and one end of the resistor R2 are connected to each other is connected to a positive-side input terminal (+) of the amplifier 11. The other end of the resistor R2 is connected to the reference voltage terminal Tref. To the reference voltage terminal Tref, a reference voltage REF is applied.

One end of the resistor R3 is connected to the positive-side input terminal Tinp. A node where the other end of the resistor R3 and one end of the resistor R4 are connected is connected to a negative-side input terminal (−) of the amplifier 11. The other end of the resistor R4 is connected to an output end of the amplifier 11.

The amplification section 10B includes the amplifier 12, and resistors R5 and R6. A positive-side input terminal (+) of the amplifier 12 is connected to the reference voltage terminal Tref. One end of the resistor R5 is connected to the output end of the amplifier 11. A node where the other end of the resistor R5 and one end of the resistor R6 are connected is connected to a negative-side input terminal (−) of the amplifier 12. The other end of the resistor R6 is connected to an output end of the amplifier 12. The output end of the amplifier 12 is connected to the output terminal To.

With this configuration, the amplification circuit 10 amplifies a voltage difference between a voltage INP applied to the positive-side input terminal Tinp and a voltage INM applied to the negative-side input terminal Tnm sequentially by the amplification sections 10A and 10B, and outputs the amplified voltage difference through the output terminal To.

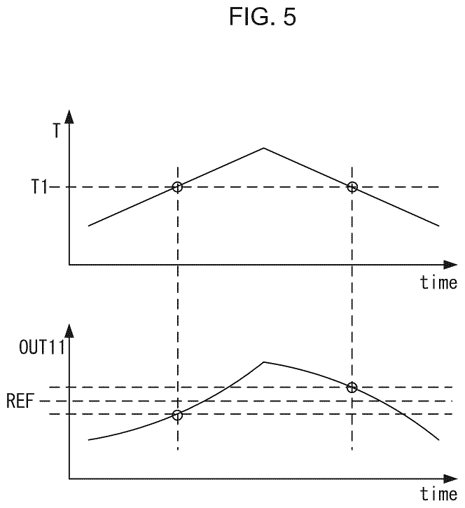

FIG. 5 is a diagram exemplarily illustrating variation in output voltage OUT11 of the amplifier 11 with temperature change. Note that the output voltage OUT11 indicates a case where the voltage difference between the voltages INP and INM is zero. Thus, if there is no offset of the amplifier 11, OUT11=REF holds.

In the example illustrated in FIG. 5, when the temperature is raised from temperature T1, which is a normal temperature, and then restored to temperature T1, the output voltage OUT11 has a value higher than its original value. It can be considered that, as described previously, this is due to the previously-described insufficient recovery of the Si interface from the deformation. Thus, in a case where the TOP conductors are thick, the occurrence of offset hysteresis is the problem to be addressed.

### 2. First Embodiment

To solve the above-described problem uniquely discovered by the inventor of the present application, the embodiments described below are implemented. To solve the above problem, an appropriate layout of the TOP conductors are required.

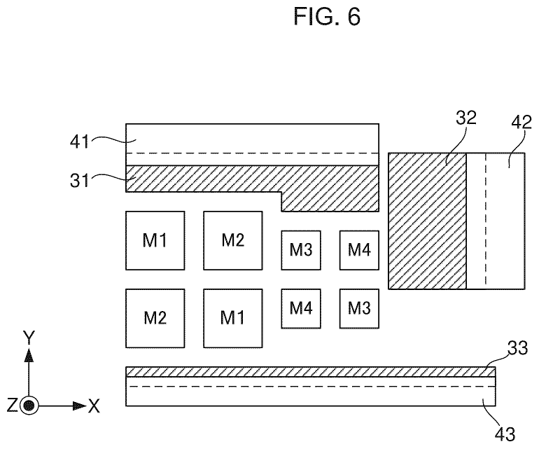

FIG. 6 is a diagram schematically illustrating an example of a conductor layout in an amplifier 1 according to a first embodiment. FIG. 6, similarly to FIG. 2A referred to previously, is a diagram in plan view, and illustrates a layout of conductors near transistors M1 to M4.

In the amplifier 1 of the present embodiment, lower layer conductors 31 to 33 and TOP conductors 41 to 43 are provided. The lower layer conductors 31 to 33 are formed in a lower layer than the TOP conductors 41 to 43. The TOP conductors 41 to 43 are thicker than the lower layer conductors 31 to 33.

The lower layer conductors 31 to 33 are provided in a manner, in plan view, similar to the TOP conductors 21 to 23 in the layout illustrated in FIG. 2A referred to previously. That is, the lower layer conductors 31 to 33 are arranged around the transistors M1 to M4 so as not to overlap with the transistors M1 to M4 in plan view. Note that, conductors that are formed in lower layers than the TOP conductor 41 to 43, including the lower layer conductors 31 to 33, are arranged, as much as possible, so as not to overlap with the transistors M1 to M4 in plan view.

As illustrated in FIG. 6, the TOP conductor 41 is formed to extend in the X direction and arranged farther on the one side in the Y direction, that is, in a direction farther away from the transistors M1 to M4, than the lower layer conductor 31. The TOP conductor 42 is formed to extend in the Y direction and arranged farther on one side in the X direction, that is, in a direction farther away from the transistors M1 to M4, than the lower layer conductor 32. The TOP conductor 43 is formed to extend in the X direction and arranged farther on the other side in the Y direction, that is, in a direction farther away from the transistors M1 to M4, than the lower layer conductor 33. Note that, as illustrated in FIG. 6, the TOP conductors 41 to 43 partly overlap with the lower layer conductors 31 to 33, respectively, in plan view (dashed lines in FIG. 6).

In this manner, in the present embodiment, the lower layer conductors 31 to 33 are arranged around the transistors M1 to M4, the TOP conductors 41 to 43 are arranged in directions farther away from the transistors M1 to M4 than the lower layer conductors 31 to 33, respectively. This makes it possible to suppress the influence of the heat stress of the thick TOP conductors 41 to 43 on the Si interface, and thus to reduce the displacement amount of the Si interface. Accordingly, it becomes possible to suppress differences in displacement amount between the transistors M1 and M2 and between the transistors M3 and M4, and thus to suppress offset hysteresis with respect to temperature change.

Note that it is preferable that the thickness of the TOP conductors 41 to 43 be equal to or larger than 3 times but equal to or smaller than 50 times the thickness of the lower layer conductors 31 to 33. It is more preferable that the thickness of the TOP conductors 41 to 43 be equal to or larger than 5 times but equal to or smaller than 20 times the thickness of the lower layer conductors 31 to 33.

### 3. Second Embodiment

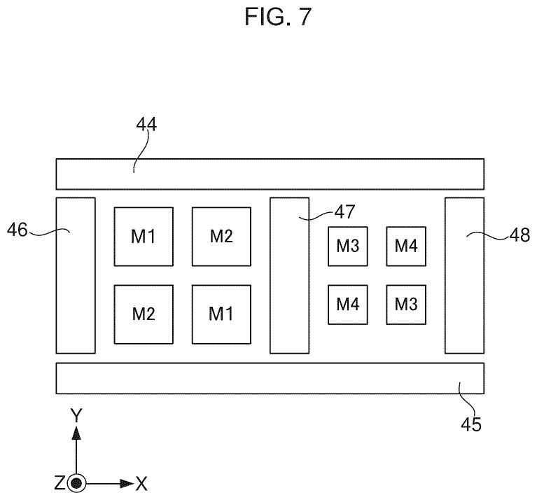

FIG. 7 is a diagram schematically illustrating an example of a conductor layout in an amplifier 1 according to a second embodiment. FIG. 7, similarly to FIG. 2A referred to previously, is a diagram in plan view, and illustrates a layout of conductors near transistors M1 to M4.

In the amplifier 1 according to the present embodiment, TOP conductors 44 to 48 are provided. The TOP conductor 44 is formed to extend in the X direction and arranged farther on the one side in the Y direction than the transistors M1 to M4 that are positioned on the one side in the Y direction. The TOP conductor 45 is formed to extend in the X direction and arranged farther on the other side in the Y direction than the transistors M1 to M4 that are positioned on the other side in the Y direction.

The TOP conductor 46 is formed to extend in the Y direction and arranged farther on the other side in the X direction than the transistor M1 of the transistors M1 and M2 that are positioned on the one side in the Y direction and the transistor M2 of the transistors M1 and M2 that are positioned on the other side in the Y direction. The TOP conductor 47 is formed to extend in the Y direction and is arranged farther on the one side in the X direction than the transistor M2 of the transistors M1 and M2 that are positioned on the one side in the Y direction and the transistor M1 of the transistors M1 and M2 that are positioned on the other side in the Y direction.

The TOP conductor 47 is formed to extend in the Y direction and arranged farther on the other side in the X direction than the transistor M3 of the transistors M3 and M4 that are positioned on the one side in the Y direction and the transistor M4 of the transistors M3 and M4 that are positioned on the other side in the Y direction. The TOP conductor 48 is formed to extend in the Y direction and arranged farther on the one side in the X direction than the transistor M4 of the transistors M3 and M4 that are positioned on the one side in the Y direction and the transistor M3 of the transistors M3 and M4 that are positioned on the other side in the Y direction.

In this manner, in the present embodiment, along four sides around the transistors M1 and M2 and four sides around the transistors M3 and M4, the TOP conductors are arranged. With this arrangement, in a case where thick Top conductors need to be arranged close to the transistors M1 to M4, although the influence of the heat stress of the TOP conductor increases, consistency in displacement amount is achieved respectively between the transistors M1 and M2 and between the transistors M3 and M4. This makes it possible to suppress offset hysteresis with respect to temperature change.

### 4. Application to Amplification Circuit

In a case where the amplifier is applied to the amplification circuit 10 illustrated in FIG. 4, which has been referred to previously, an offset of the amplifier 11 of the first stage is important. Accordingly, in the case where the amplifier 1 according to either of the embodiments described above is applied to the amplification circuit 10, it needs to be applied at least to the amplifier 11 of the first stage.

Further, in a case where, of the amplification section 10A of the first stage and the amplification section 10B of the second stage, a larger amplification factor is assigned to the amplification section 10B of the second stage (e.g., the amplification factor is 1 at the amplification section 10A, and 100 at the amplification section 10B), it is preferable that the amplifier 1 of either of the embodiments described previously be also applied to the amplification section 10B of the second stage, in addition to the amplification section 10A of the first stage.

Note that the amplification circuit 10 may include a plurality of stages (more than two stages) of amplifiers. For example, in a case where the amplification circuit 10 includes four stages of amplifiers, if the maximum amplification factor is assigned to the amplifier of the third stage, the amplifier 1 of either of the embodiments described previously is applied at least to the amplifiers from the first stage through the third stage.

### 5. Application to Applications

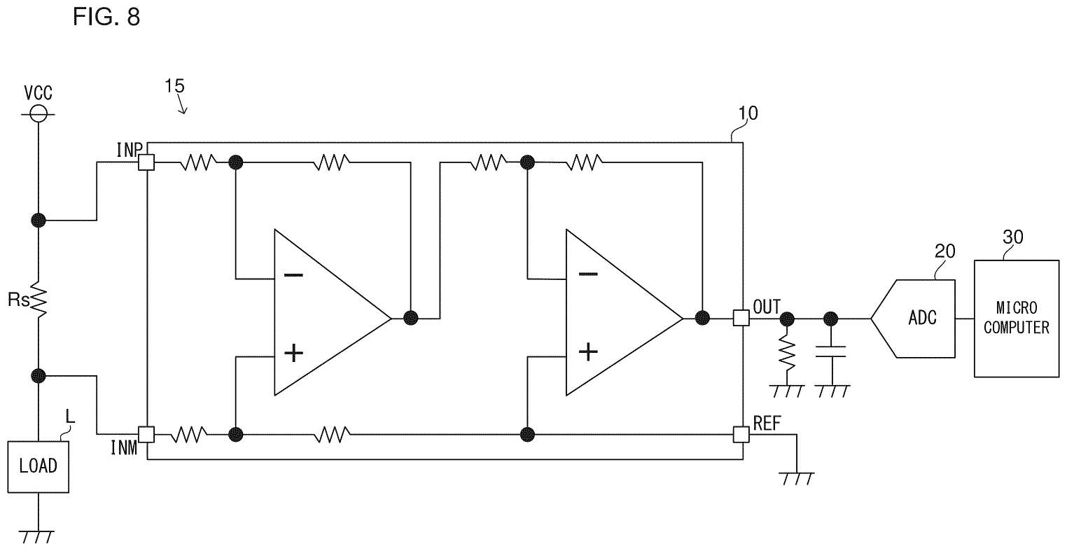

The amplifier 1 according to each of the embodiments described previously is applicable to various applications. FIG. 8 is a diagram illustrating, as an example of an application, a configuration of a case where the amplification circuit 10 is applied to a current detection device 15.

The current detection device 15 illustrated in FIG. 8 includes the amplification circuit 10 and a sense resistor Rs. The amplification circuit 10 illustrated in FIG. 8 is configured as illustrated in FIG. 4, and the amplifier 1 of either of the embodiments described previously is applied to it. One end of the sense resistor Rs is connected to a power supply voltage VCC application end. The other end of the sense resistor Rs is connected to a load L. The one end of the sense resistor Rs is connected to the positive-side input terminal Tinp of the amplification circuit 10. The other end of the sense resistor Rs is connected to the negative-side input terminal Tinm of the amplification circuit 10.

With this configuration, a load current flowing through the load L is subjected to current-to-voltage conversion by the sense resistor Rs, and is then fed to the amplification circuit 10 as a voltage difference between the voltages INP and INM. A voltage after being amplified by the amplification circuit 10 is outputted as an output OUT through the output terminal To. The output OUT is subjected to AD conversion by an ADC (AD converter) 20, so as to be fed to a microcomputer 30.

Note that the amplification circuit 10 is applicable, in addition to the current detection device 15, to a magnetic sensor, a pressure sensor, an in-vehicle sensor AFE (Analog Front-End), a medical sensor AFE, or the like, for example.

### 6. Others

Other than the embodiments described above, various technical features disclosed in this specification can be variously modified within the scope without deviating from the spirit of the technical invention. That is, it should be considered that the above embodiments are illustrative in all respects and are not limiting, and it should be understood that the technological scope of the present disclosure is not limited to the above description of the embodiments, and that all modifications within the scope of the claims and the meaning equivalent to the claims are covered.

### 7. Supplementary Notes

As hitherto described, for example, according to one aspect of the present disclosure, an amplifier (1) includes a first transistor (M1), a second transistor (M2) arranged adjacent to the first transistor in plan view, a first conductor (31) arranged around the first transistor and the second transistor in plan view, and a second conductor (41) arranged, in plan view, in a direction farther away from the first transistor and the second transistor than the first conductor, the second conductor having a thickness that is greater than a thickness of the first conductor (a first configuration, FIG. 6).

Further, in the above-described first configuration, the second conductor (41) may be arranged above the first conductor (31) (a second configuration).

Further, in the above-described second configuration, the second conductor (41) may be arranged in an uppermost wiring layer of a plurality of wiring layers (a third configuration).

Further, in any one of the above-described first to third configurations, the second conductor (41) may have a thickness that is equal to or greater than five times, but equal to or smaller than twenty times, the thickness of the first conductor (31) (a fourth configuration).

Further, according to another aspect of the present disclosure, an amplifier (1) includes a third transistor (M1), a fourth transistor (M2) arranged, in plan view, adjacent to the third transistor in a first direction (an X direction), a third conductor (44) that, in plan view, is formed to extend in the first direction and arranged farther on one side in a second direction (a Y direction) than the third transistor and the fourth transistor, the second direction being orthogonal to the first direction, and fourth and fifth conductors (46, 47) that, in plan view, are formed to extend in the second direction and arranged so as to sandwich the third transistor and the fourth transistor from opposite sides in the first direction (a fifth configuration, FIG. 7).

Further, in the above-described fifth configuration, there may further be included a fifth transistor (M1) arranged, in plan view, on a first diagonal line so as to be diagonally opposite to the third transistor (M1); a sixth transistor (M2) arranged, in plan view, on a second diagonal line so as to be diagonally opposite to the fourth transistor (M2), the second diagonal line crossing the first diagonal line; and a sixth conductor (45) that, in plan view, is formed to extend in the first direction and arranged farther on an other side in the second direction than the fifth transistor and the sixth transistor (a sixth configuration).

Further, according to another aspect of the present disclosure, an amplification circuit (10) includes a plurality of stages of amplifiers (11, 12), the amplifier (1) having any one of the above-described first to sixth configurations being applied at least to the amplifier (11) of a first stage (a seventh configuration, FIG. 4).

Further, in the above-described seventh configuration, the amplifier (1) having any one of the above-described first to sixth configurations may be applied at least to the amplifier (11) of the first stage through the amplifier (12) of a stage with a maximum amplification factor assigned (an eighth configuration).

Further, according to another aspect of the present disclosure, a current detection device (15) includes a sense resistor (Rs) configured to be capable of performing current-voltage conversion on a current flowing through a load (L), and the amplification circuit (10) having the above-described seventh or eighth configuration, the amplification circuit further including a positive-side input terminal (Tinp) connectable to a first end of the sense resistor, and a negative-side input terminal (Tinm) connectable to a second end of the sense resistor (a ninth configuration).

### INDUSTRIAL APPLICABILITY

The present disclosure is usable in amplification circuits for various uses, for example.

### LIST OF REFERENCE SIGNS

1 amplifier
1A differential input section
1B output section
10 amplification circuit
10A, 10B amplification section
11,12 amplifier
15 current detection device
20 AD converter
21 to 23 TOP conductor
30 microcomputer
31 to 33 lower layer conductor
41 to 48 TOP conductor
CI constant current source
L load
M1, M2 PMOS transistor
M3, M4 NMOS transistor
R1 to R6 resistor
Rs sense resistor
S1 Si interface
Tinp positive-side input terminal
Tinm negative-side input terminal
Tn negative-side input terminal
To output terminal
Tout output terminal
Tp positive-side input terminal
Tref reference voltage terminal

1. An amplifier, comprising:
a first transistor,
a second transistor arranged adjacent to the first transistor in plan view,
a first conductor arranged around the first transistor and the second transistor in plan view; and
a second conductor arranged, in plan view, in a direction farther away from the first transistor and the second transistor than the first conductor,
wherein
the second conductor has a thickness that is greater than a thickness of the first conductor.

2. The amplifier according to claim 1,
wherein
the second conductor is arranged above the first conductor.

3. The amplifier according to claim 2,
wherein
the second conductor is arranged in an uppermost wiring layer of a plurality of wiring layers.

4. The amplifier according to claim 1,
wherein
the second conductor has a thickness that is equal to or greater than five times, but equal to or smaller than twenty times, the thickness of the first conductor.

5. An amplifier, comprising:
a third transistor,
a fourth transistor arranged, in plan view, adjacent to the third transistor in a first direction,
a third conductor that, in plan view, is formed to extend in the first direction and arranged farther on one side in a second direction than the third transistor and the fourth transistor, the second direction being orthogonal to the first direction; and
fourth and fifth conductors that, in plan view, are formed to extend in the second direction and arranged so as to sandwich the third transistor and the fourth transistor from opposite sides in the first direction.

6. The amplifier according to claim 5, further comprising:
a fifth transistor arranged, in plan view, on a first diagonal line so as to be diagonally opposite to the third transistor;
a sixth transistor arranged, in plan view, on a second diagonal line so as to be diagonally opposite to the fourth transistor, the second diagonal line crossing the first diagonal line; and
a sixth conductor that, in plan view, is formed to extend in the first direction and arranged farther on an other side in the second direction than the fifth transistor and the sixth transistor.

7. An amplification circuit, comprising:
a plurality of stages of amplifiers,
wherein
the amplifier according to claim 1 is applied at least to the amplifier of a first stage.

8. The amplification circuit according to claim 7,
wherein
the amplifier according to any one of the first to sixth claims is applied at least to the amplifier of the first stage through the amplifier of a stage with a maximum amplification factor assigned.

9. A current detection device, comprising:
a sense resistor configured to be capable of performing current-voltage conversion on a current flowing through a load; and
the amplification circuit according to claim 7,
wherein
the amplification circuit further includes
a positive-side input terminal connectable to a first end of the sense resistor, and
a negative-side input terminal connectable to a second end of the sense resistor.
